(19) United States
(12) Patent Application Publication
(10) Pub. No.: US 2011/0186118 A1
(43) Pub. Date: Aug. 4, 2011

(54) METHOD OF DOPING IMPURITIES, METHOD OF MANUFACTURING A SOLAR CELL USING THE METHOD AND SOLAR CELL MANUFACTURED BY USING THE METHOD

(76) Inventor: SANG-HO KIM, Seoul (KR)

(21) Appl. No.: 12/888,939

(22) Filed: Sep. 23, 2010

(30) Foreign Application Priority Data
Feb. 1, 2010 (KR) 2010-0008925

(51) Int. Cl. H01L 31/02; H01L 31/18; B05D 5/12

(52) U.S. Cl. 136/256; 438/69; 427/126.2; 257/E31.001

(57) ABSTRACT

There are provided a method of doping impurities, a method of manufacturing a solar cell, and a solar cell. In the doping method, a diffusion protective pattern having at least one opening is formed on a substrate that contains a first area and a second area. A first dopant is doped in the first area by using a first mask to form a first doped pattern. A second dopant is doped in the second area by using a second mask to form a second doped pattern. The first dopant and the second dopant may be doped in neighboring first and second areas, respectively, without creating a short circuit by using the first mask, the second mask, and the diffusion protective pattern.

### CROSS-REFERENCE TO RELATED APPLICATION

This application claims priority under 35 U.S.C. §119 to Korean Patent Application No. 2010-8925, filed on Feb. 1, 2010 in the Korean Intellectual Property Office (KIPO), the contents of which are herein incorporated by reference in their entirety.

### BACKGROUND

1. Technical Field

Exemplary embodiments of the present invention relate to a method of doping impurities, a method of manufacturing a solar cell using the method, and a solar cell manufactured by using the method. More particularly, exemplary embodiments of the present invention relate to a method of doping impurities used for manufacturing a solar cell having a rear surface electrode, a method of manufacturing a solar cell using the method, and a solar cell manufactured by using the method.

2. Discussion of the Related Art

Semiconductors may be classified into P-type semiconductors and N-type semiconductors in accordance with the type of doped impurities. Impurities are doped into a wafer formed of a Group IV element, such as silicon (Si) or germanium (Ge) to produce a P-type semiconductor or N-type semiconductor.

Impurity doping may be typically performed by a thermal diffusion process or an ion implantation process. In the thermal diffusion process, a wafer and gas are heated at a high temperature so that the gas is diffused onto the wafer. In the ion implantation process, P-type or N-type impurities are implanted into a wafer by ion beams. Generally, both the thermal diffusion and ion implantation may implant a high concentration of impurities into a wafer, and thus, may produce a semiconductor having excellent electrical conductivity. However, since the processes are performed at a high temperature of about 850° C. or more, a produced semiconductor can have crystal defects that may decrease resistance of the semiconductor.

A solar cell is an energy conversion element which converts light energy into electric energy using a photovoltaic effect. When light is incident onto a surface of the solar cell, electrons and holes are generated. As the electrons and holes respectively move toward an N polarity and a P polarity, a photoelectromotive force is generated between the P polarity and the N polarity. At this time, when a load is connected to the solar cell, a current flows across the load. The solar cell includes a P-type semiconductor as the P polarity and an N-type semiconductor as the N polarity.

However, manufacturing the solar cell by using the thermal diffusion or the ion implantation may increase manufacturing costs due to a high cost of a photoresist

### SUMMARY

Exemplary embodiments of the present invention provide a method of doping impurities which is capable of reducing manufacturing costs, a method of manufacturing a solar cell using the above-mentioned method, and a solar cell manufactured by using the above-mentioned method.

According to an embodiment of the present invention, there is provided a method of doping impurities. The diffusion protective pattern has at least one opening that corresponds to a first area or a second area. In the method, a diffusion protective pattern is formed on a substrate that contains the first area and the second area. Then, a first dopant is doped in the first area by using a first mask to form a first doped pattern. Then, a second dopant is doped in the second area by using a second mask to form a second doped pattern.

According to an embodiment of the present invention, there is provided a method of manufacturing a solar cell. In the method, a diffusion protective pattern is formed to have a first thickness on a substrate having a first area and a second area. Then, a first dopant is doped in the first area by using a first mask to form a first doped pattern and a second dopant is doped in the second area by using a second mask to form a second doped pattern. Then, the diffusion protective pattern is removed after the first and second doped patterns are formed. Then, a first metal pattern electrically connected to the first doped pattern and a second metal pattern electrically connected to the second doped pattern are formed on a first surface of the substrate. The diffusion protective pattern has at least one opening that corresponds to the first area or the second area, wherein the first metal pattern and the second metal pattern are spaced apart from each other.

According to an embodiment of the present invention, a solar cell includes a substrate, a first metal pattern, and a second metal pattern. The substrate includes a first doped pattern, a second doped pattern, a first low density pattern, and a second low density pattern. The first doped pattern is formed on a first substrate of the substrate and doped with a first dopant. The second doped pattern is formed on the first substrate of the substrate and doped with a second dopant. The first low density pattern has a lower concentration than the first doped pattern and is formed between the first and second doped patterns. The second low density pattern has a lower concentration than the second doped pattern and is formed between the first and second doped patterns. The first metal pattern is formed on a first surface of the substrate to be electrically connected to the first doped pattern. The second metal pattern is formed on the first surface of the substrate to be electrically connected to the second doped pattern. The second metal pattern is spaced apart from the first metal pattern.

According to exemplary embodiments of the present invention, a first dopant and a second dopant may be doped in neighboring first and second areas, respectively, without creating a short circuit by using a first mask, a second mask, and a diffusion protective pattern. Thus, manufacturing costs and processing time may be reduced and high-efficiency solar cells may be manufactured.

### BRIEF DESCRIPTION OF THE DRAWINGS

The embodiments of the present invention will become more apparent by describing in detailed exemplary embodiments thereof with reference to the accompanying drawings, in which:

FIG. 1 is a rear perspective view schematically showing a solar cell manufactured in accordance with an exemplary embodiment of the present invention;

FIG. 2 is a cross-sectional view taken along a line I-I′ of FIG. 1;

FIGS. 3A, 3B, 3C, 3D, 3E, 3F, 3Q 3H and 3I are process diagrams schematically illustrating a method of manufacturing the solar cell of FIG. 2;

FIG. 4 is a cross-sectional view showing a solar cell manufactured in accordance with an exemplary embodiment of the present invention; and

FIGS. 5A, 5B, 5C and 5D are process diagrams schematically illustrating a method of manufacturing the solar cell of FIG. 4.

### DETAILED DESCRIPTION OF THE EMBODIMENTS

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Like numerals may refer to like elements throughout the drawings and the specification.

Hereinafter, the embodiment of the present invention will be described in detail with reference to the accompanying drawings.

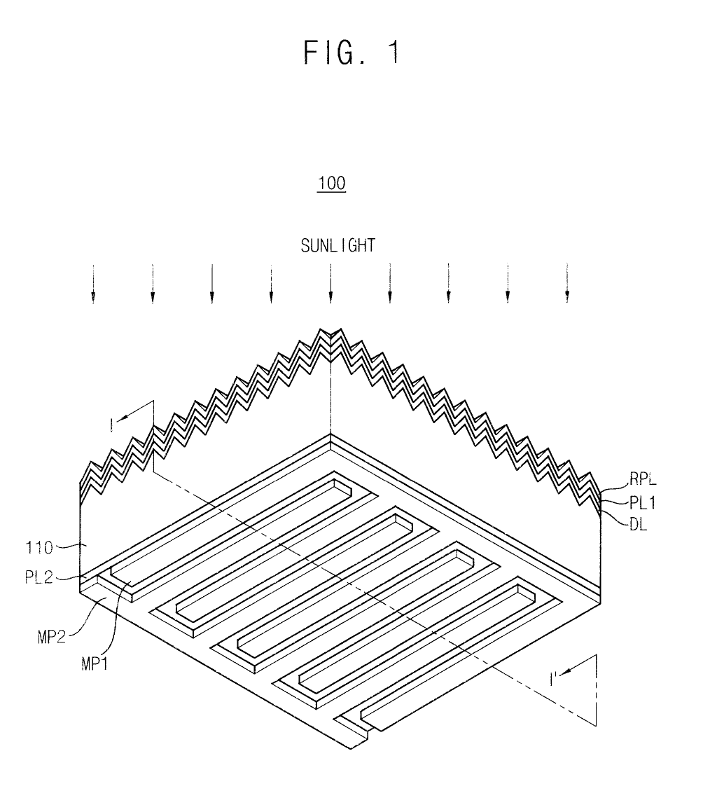

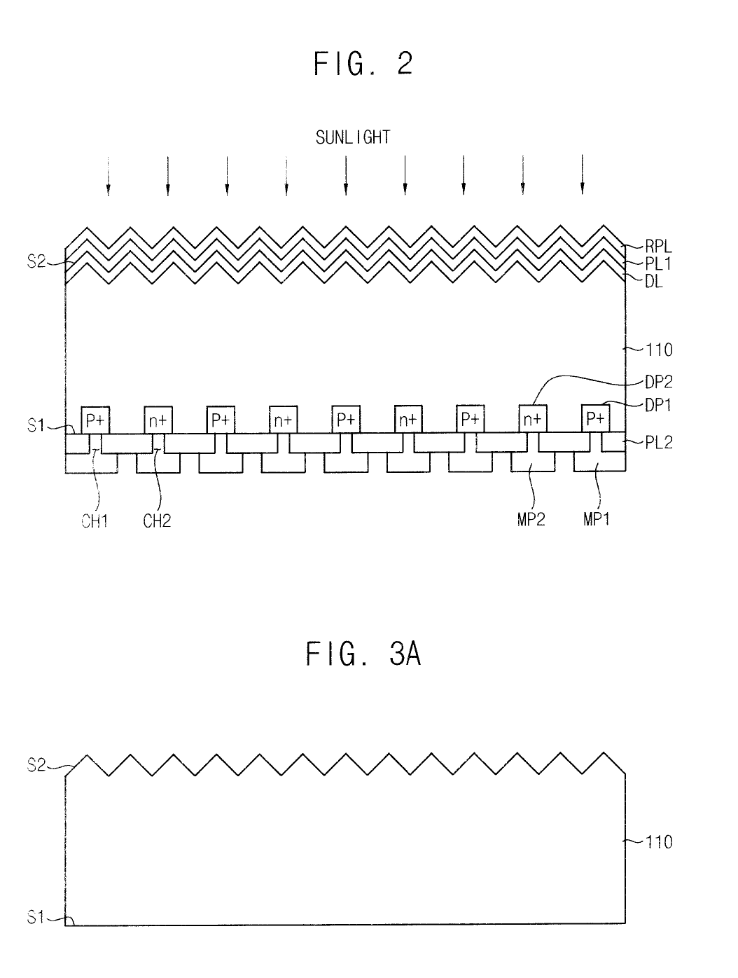

FIG. 1 is a rear perspective view schematically showing a solar cell manufactured in accordance with an exemplary embodiment of the present invention. FIG. 2 is a cross-sectional view taken along a line I-I′ of FIG. 1.

Referring to FIGS. 1 and 2, a solar cell 100 according to an exemplary embodiment includes a base substrate 110, a second passivation layer PL2, a first metal pattern MP1, and a second metal pattern MP2. A first doped pattern DP1 and a second doped pattern DP2 are formed on a first surface S1 of the base substrate 110. The second passivation layer PL2 is formed on the first surface S1 of the base substrate 110. The first metal pattern MP1 and a second metal pattern MP2 are formed on the second passivation layer PL2 to be electrically connected to the first doped pattern DP1 and the second doped pattern DP2, respectively. The first and second metal patterns MP1 and MP2 are spaced apart from each other. The first doped pattern DP1 is electrically connected to the first metal pattern MP1 through a first contact hole CH1 formed through the second passivation layer PL2. The second doped pattern DP2 is electrically connected to the second metal pattern MP2 through a second contact hole CH2 formed through the second passivation layer PL2. The first and second doped patterns DP1 and DP2 may be a P⁺ area and an N⁺ area, respectively.

Light, such as sunlight, is incident onto a second surface S2 of the base substrate 110. Thus, the first surface S1 may be a rear surface of the solar cell 100, so that the first and second metal patterns MP1 and MP2 may be rear electrodes.

In a case of a conventional solar cell, since a metal finger line is protruded from the second surface S2, a shadow is generated. The shadow may decrease the collecting area of irradiated light, and as a result, lower efficiency of the solar cell. However, according to an embodiment, the first and second metal patterns MP1 and MP2 as rear electrodes are formed on a rear surface of the solar cell 100, so that efficiency of the solar cell 100 may be enhanced in comparison with the conventional solar cell.

When the second surface S2 has a convex-concave pattern, the second surface S2 may minimize the light reflectance. A doped layer DL may be formed on the second surface S2 of the base substrate 110. The doped layer DL may include an N⁺ area. A first passivation layer PL1 including oxide is formed on the doped layer DL to protect the solar cell 100, and a reflection protective layer RPL including, for example, silicon nitride (SiNx) is formed on the first passivation layer PL1. The first passivation layer PL1 may enhance efficiency of the solar cell 100 by stabilizing the second surface S2 to protect the solar cell 100 and minimizing the recoupling of an electron and a hole at a surface of the first passivation layer PL1. The reflection protective layer RPL may minimize reflection of light incident onto the doped layer DL similarly to the convex-concave pattern. Moreover, the reflection protective layer RPL may enhance efficiency of the solar cell 100 by minimizing the recoupling of an electron and a hole at a surface of the reflection protective layer RPL.

The base substrate may be an N-type silicon substrate. That is, the base substrate 110 may include a Group IV element and a Group V element.

The first doped pattern DP1 may include a P-type semiconductor (i.e., a P⁺ semiconductor) including a first dopant. The first dopant may include a Group III element, such as boron (B), aluminum (Al), etc. The first doped pattern may be an emitter layer that has a conductive type opposite to that of the base substrate 110. As the first doped pattern DP1 is formed, a PN junction of the solar cell 100 is achieved.

The second doped pattern DP2 and the doped layer DL may include an N-type semiconductor doped with a second dopant. The second doped pattern DP2 may include an N-type semiconductor (i.e., N+ semiconductor) doped with an N-type dopant of a higher concentration than that of the doped layer DL. That is, the concentration of the second dopant of the second doped pattern DP2 is higher than that of the second dopant of the doped layer DL, so that the doped layer DL may push electrons generated in the base substrate 110 by light toward the second doped pattern DP2. The second dopant may include a Group V element, such as phosphorus (P), arsenic (As), etc.

Hereinafter, a principle of generating electric power by the solar cell 100 will be explained. When light is incident onto the second surface S2 of the solar cell 100, holes and electrons are generated in the base substrate 110 due to the light energy. The holes and electrons move toward the first doped pattern DP1 and the second doped pattern DP2, respectively, due to an electric field generated by the PN junction between the base substrate 110, which is an N-type silicon substrate, and the first doped pattern DP1. The holes moved to the first doped pattern DP1 are accumulated in the first metal pattern MP1, and the electrodes moved to the second doped pattern DP2 are accumulated in the second metal pattern MP2. Due to the electrons and holes respectively accumulated in the first metal pattern MP1 and the second metal pattern MP2, an electric potential difference is generated between the first metal pattern MP1 and the second metal pattern MP2 of the solar cell 100. As a result, the solar cell 100 may produce electric power.

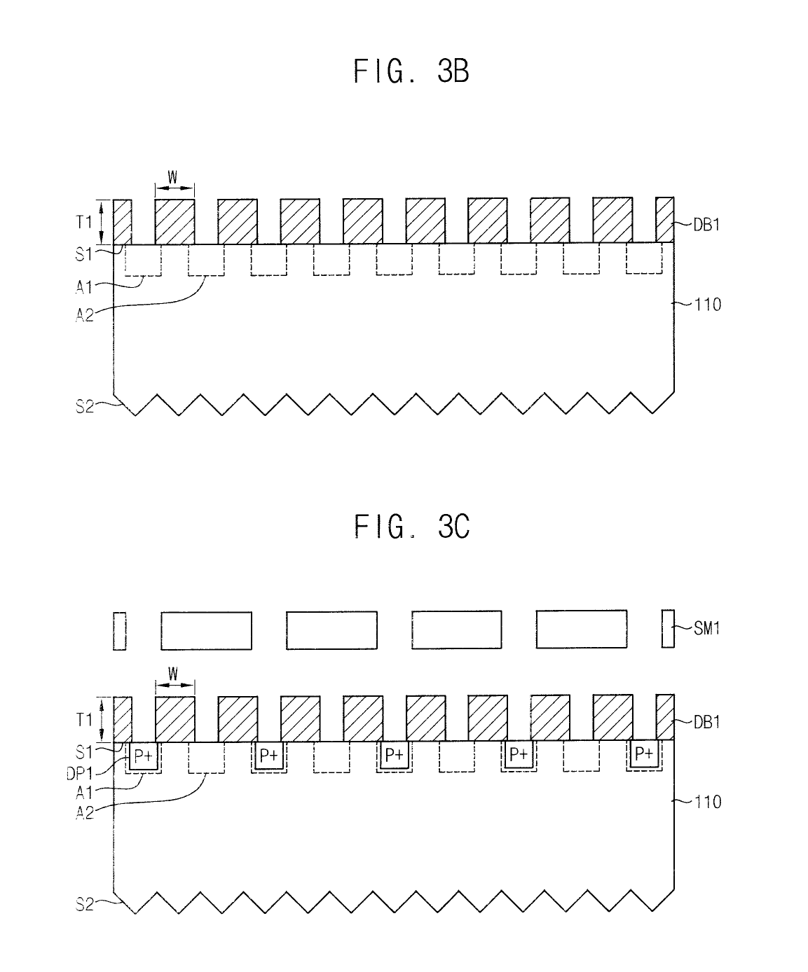

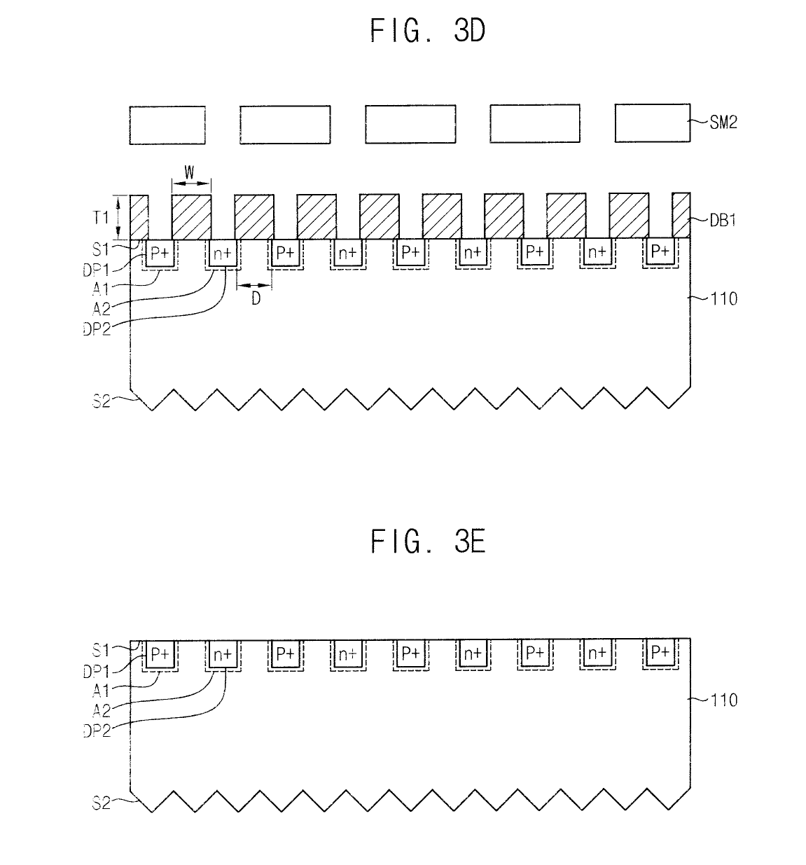

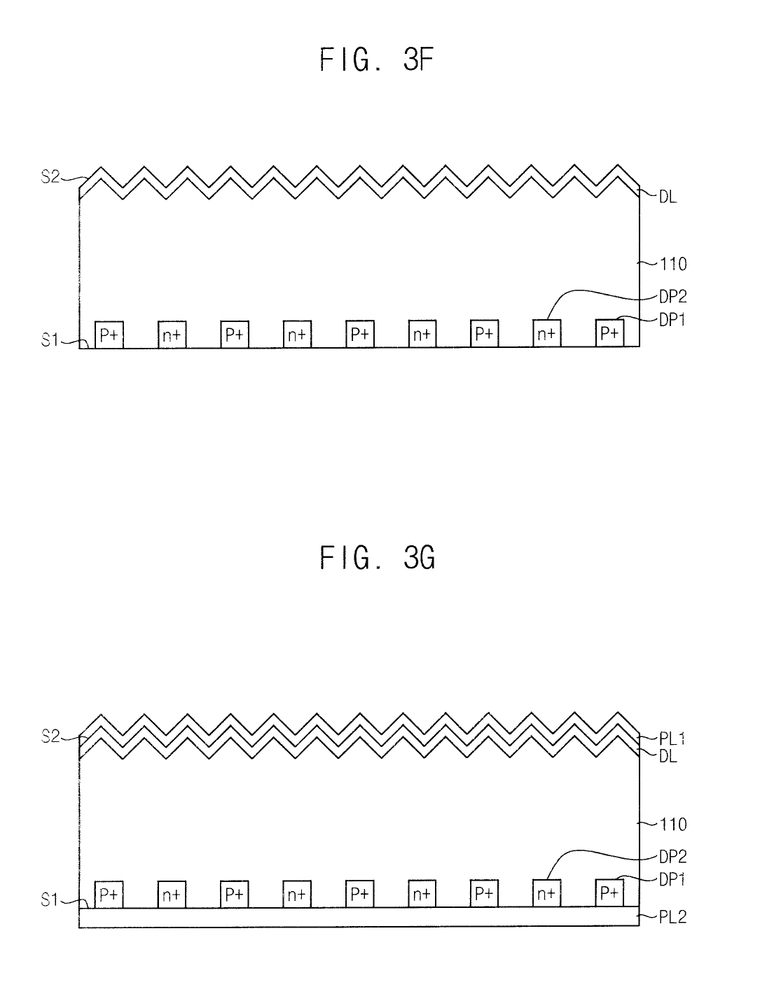

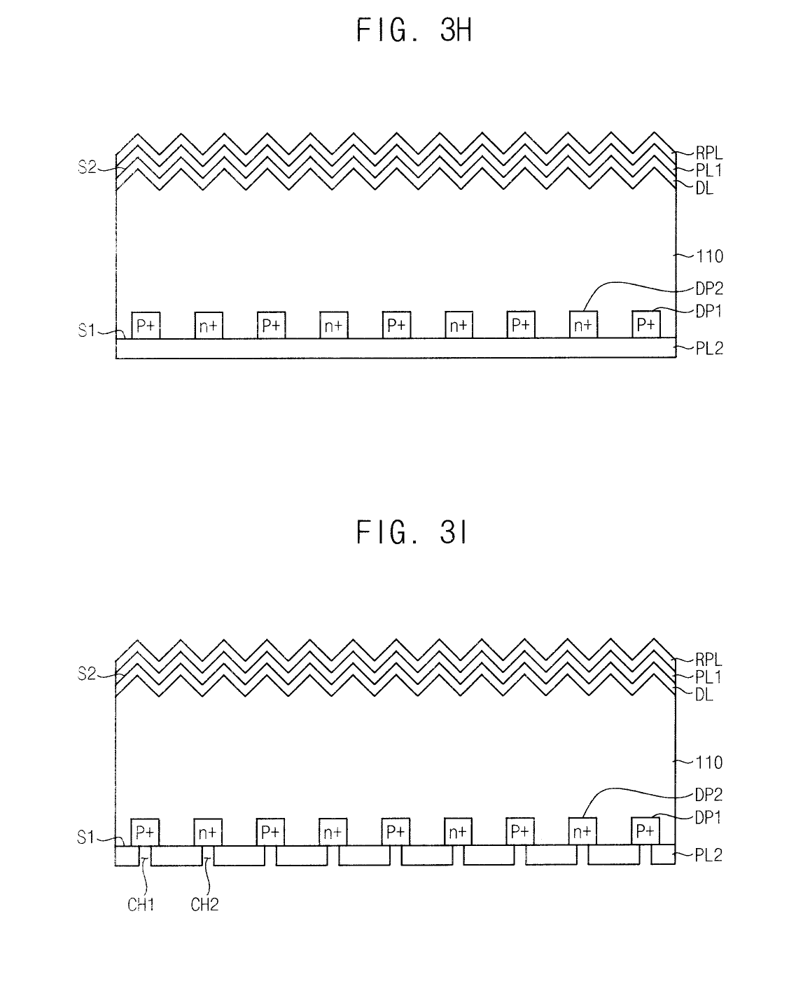

FIGS. 3A, 3B, 3C, 3D, 3E, 3F, 3G, 3H and 3I are process diagrams schematically illustrating a method of manufacturing the solar cell of FIG. 2.

Referring to FIGS. 2 and 3A, the base substrate 110, an N-type silicon substrate, is cut to a predetermined size. The cut surface of the base substrate 110 may be partially etched. Defects generated during cutting the base substrate 110 may be removed through a wet etching process using an alkaline solution or an acid solution. Although it has been described to use the N-type silicon substrate, the present invention is not limited thereto, and alternatively, a P-type silicon substrate may be used for the base substrate 110.

Then, in order to minimize light reflectance, a convex-concave pattern is formed on at least one of a first surface S1 and a second surface S2 of the base substrate 110 by using, for example, an alkaline solution. While the convex-concave pattern is formed on the second surface S2 of the base substrate 110, the first surface S1 of the base substrate 110 may be grinded to planarize the first surface S1.

Referring to FIGS. 2 to 3B, a diffusion protective pattern DB1 is formed over the first surface S1 to include at least one opening that corresponds to the first area A1 or the second area A2. The diffusion protective pattern DB1 may include at least one of silicon oxide (SiOx) and silicon nitride (SiNx).

The diffusion protective pattern DB1 may be formed by patterning a diffusion protective layer to have the opening that corresponds to the first area A1 and/or the second area A2. For example, photoresist is deposited on the diffusion protective layer and then a mask is applied on the photoresist which has an opening pattern that corresponds to the first and second regions A1 and A2. Then, the photoresist is exposed to light to selectively remove the diffusion protective layer, thereby completing the diffusion protective pattern DB1.

The diffusion protective pattern DB1 may be printed on the first surface S1 by using, for example, a screen printing method or an ink printing method to further reduce manufacturing costs. For example, diffusion protective paste or diffusion protective ink may be directly printed on the first surface 51 of the base substrate 110.

Referring to FIGS. 2, 3B and 3C, a first mask SM1 that has at least one opening corresponding to the first area A1 is disposed over the base substrate 110 to dope the first area A1 with the first dopant. Thus, the first doped pattern DP1 may be formed at the first area A1.

Referring to FIGS. 2, 3C and 3D, a second mask SM2 that has at least one opening corresponding to the second area A2 is disposed over the base substrate 110 to dope the second area A2 with the second dopant. Thus, the second doped pattern DP2 may be formed at the second area A2.

In this case, each of the first and second masks SM1 and SM2 may be a shadow mask.

Referring again to FIGS. 3B and 3C, when the first dopant is doped in the first area A1 of the base substrate 110 by using the first mask and the second dopant is doped in the second area A2 of the base substrate 110 by using the second mask, the diffusion protective pattern DB1 may prevent the first dopant from being doped outside of the first area A1 and the second dopant from being doped outside of the second area A2. Thus, the first doped pattern DP1 doped with the first dopant and the second doped pattern DP2 doped with the second dopant may be spaced apart from each other, thereby preventing a short circuit between the first doped pattern DP1 and the second doped pattern DP2.

While the first mask SM1 and the second mask SM2 are spaced apart from the base substrate 110 by a predetermined distance, the first and second dopant ions may be implanted into the first and second areas A1 and A2. In the ion implantation process, ions emitted from an ion source (not shown) may be infiltrated into the first and second areas A1 and A2 through the openings of the first and second masks SM1 and SM2, respectively.

Using the first and second masks SM1 and SM2 in ion implanting or impurity doping may eliminate the need for exposing, developing, etching, and stripping processes required for the conventional photolithography, thereby saving manufacturing costs and processing time.

However, performing doping of the first and second dopants only by using the first and second masks SM1 and SM2 may cause a misalignment between the first mask SM1 and the first area A1 or between the second mask SM2 and the second area A2, which, in turn, may decrease doping accuracy in comparison with the conventional photolithography method.

According to an exemplary embodiment, the diffusion protective pattern DB1 prevents the misalignment between the first mask SM1 and the first area A1 or between the second mask SM2 and the second area A2, thereby enhancing doping accuracy.

By patterning the diffusion protective pattern DB1 through a photolithography method, arranging accuracy of the diffusion protective pattern DB1 may be increased. In this case, since photolithography is performed only once, the manufacturing process may be simplified in comparison with performing photolithography for each of the first and second doped patterns DP1 and DP2.

If the diffusion protective pattern DB1 is patterned through a screen printing method or an ink printing method, the manufacturing process may be further simplified because of the elimination of a complicated photolithography method.

A width ‘W’ of at least one protrusion of the diffusion protective pattern DB1, i.e., an interval between two neighboring openings of the diffusion protective pattern DB1, may be larger than an interval between the neighboring first doped pattern DP1 and second doped pattern DP2. For example, the interval between the first doped pattern DP1 and the second doped pattern DP2 may be about 10 μm, and the width ‘W’ of the diffusion protective pattern DB1 may be about 1 μm to about 300 μm. A first thickness T1 of the diffusion protective pattern DB1 may be about 0.5 μm to about 300 μm.

The first and second dopants may be doped by using an ion implantation method. During the ion implantation method, a doped density, a PN junction depth, etc. may be controlled through gas flow control, and thus may achieve higher accuracy and reproducibility than a high temperature diffusion method. Moreover, because of being performed at a relatively low temperature, the ion implantation method does not generate by-products unlike the high temperature diffusion method. Accordingly, an additional process for removing the by-product is not needed, thus improving productivity.

Although it has been described that after the formation of the convex-concave pattern on the base substrate 110, the first and second doped patterns DP1 and DP2 are formed, the first and second doped patterns DP1 and DP2 may be first formed and then the convex-concave pattern may be formed on the first base substrate 110.

Referring to FIGS. 2, 3D and 3E, the diffusion protective pattern DB1 is removed.

Referring to FIGS. 2, 3E and 3F, the second dopant may be doped on the second surface S2 to form the doped layer DL.

Referring to FIGS. 2, 3F and 3G, the second passivation layer PL2 and the first passivation layer PL1, each of which may be made of oxide, are respectively formed on the first surface S1, on which the first doped pattern DP1 and th second doped pattern DP2 are formed, and on the second surface S2, on which the doped layer DL is formed. According to an embodiment, the first and second passivation layers PL1 and PL2 may be simultaneously formed. Alternatively, the second passivation layer PL2 may be also formed while the first surface S1 is formed after the formation of the reflection protective layer 150.

The first and second passivation layers PL1 and PL2 may be made of an oxide, such as, for example, silicon oxide (SiOx), which is formed through a high speed heat oxidation process. The first and second passivation layers PL1 and PL2 may be formed through a sputtering process targeting silicon oxide (SiOx).

Referring to FIGS. 2, 3G and 3H, the reflection protective layer RPL is formed of silicon nitride (SiNx) or titanium dioxide (TiO₂) on the first passivation layer PL1. The reflection protective layer RPL may be deposited on the first passivation layer PL1 through various deposition processes, such as plasma enhanced chemical vapor deposition (“PECVD”), a sputtering process, a spin coating process, etc.

Referring to FIGS. 2, 3H and 3I, the second passivation layer PL2 is removed to expose the first and second doped patterns DP1 and DP2, thus forming at least one first contact hole CH1 and at least one second contact hole CH2.

Then, the first metal pattern MP1 and the second metal pattern MP2, which are spaced from each other, are formed on the base substrate 110 and the second passivation layer PL2 to cover the first contact hole CH1 and the second contact hole CH2, respectively. The first and second metal patterns MP1 and MP2 may be made of a conductor, such as silver (Ag).

Thus, holes from the first doped pattern DP1 and electrons from the second doped pattern DP2 may be accumulated in the first metal pattern MP1 and the second metal pattern MP2, respectively, so that the solar cell 100 may produce electricity by using light.

According to an embodiment, the first dopant and the second dopant may be respectively doped in the first area A1 and the second area A2 of the base substrate 110 by using the first mask SM1 and the second mask SM2, respectively, so that a manufacturing cost and a processing time may be decreased. Moreover, as an interval between the first doped pattern DP1 and the second doped pattern DP2 is reduced, an efficiency of the solar cell 100 may be further enhanced. In this case, the diffusion protective pattern DB1 allows the first and second dopants to be accurately doped in the first and second areas A1 and A2, respectively, thus preventing a short circuit that may occur due to a misalignment between the first doped pattern DP1 and the second doped pattern DP2. Thus, a high efficiency solar cell may be manufactured.

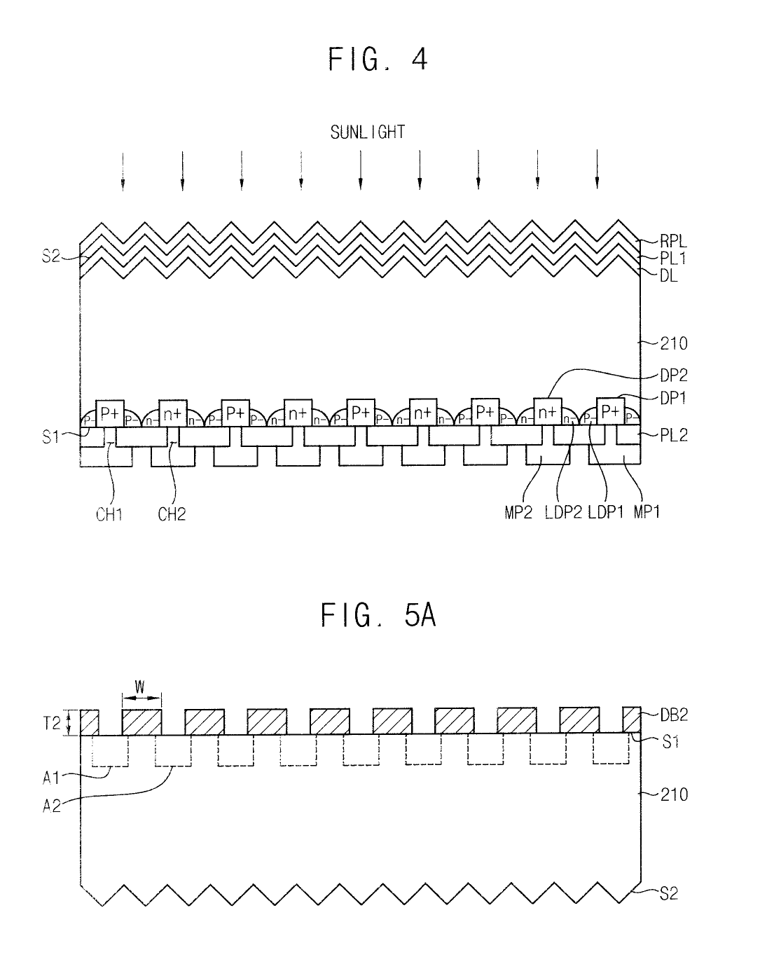

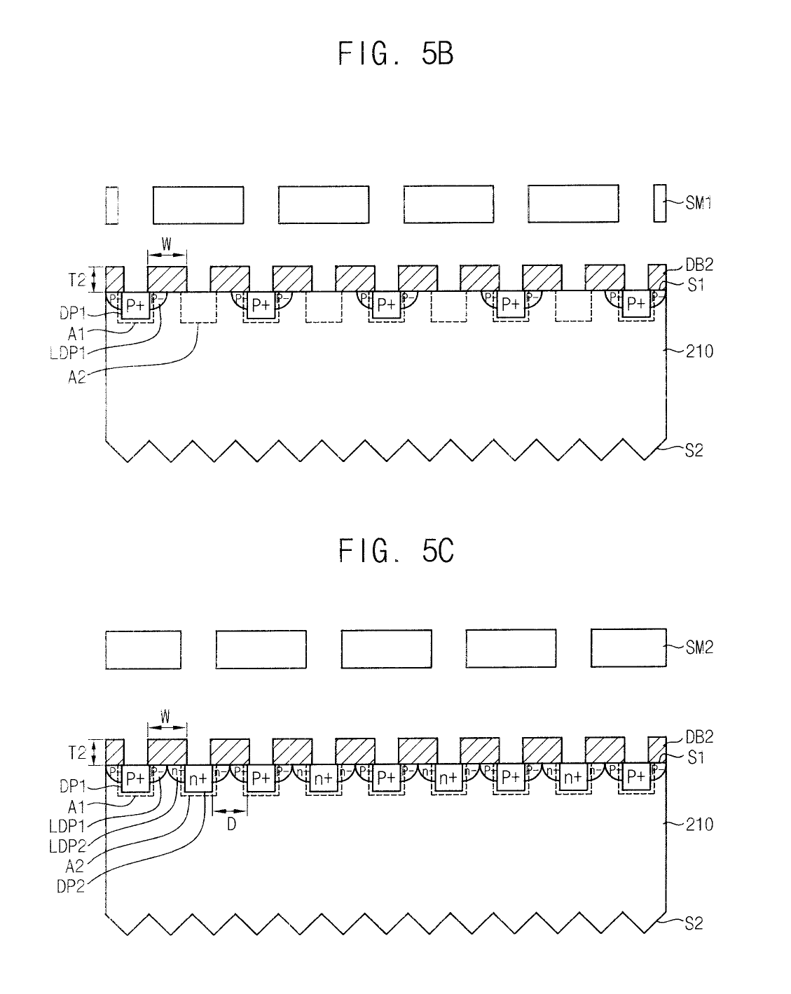

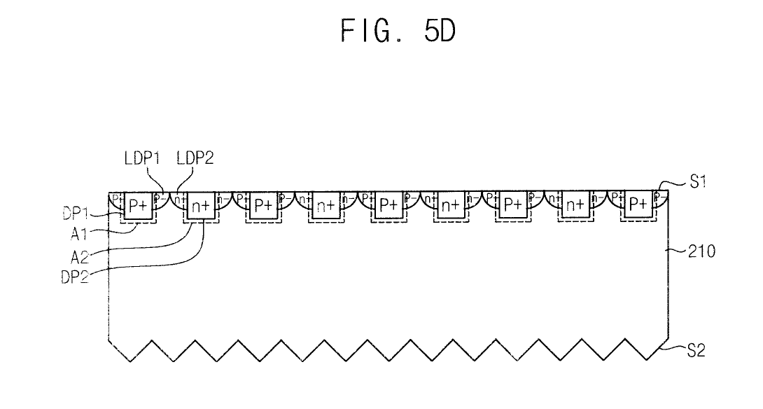

FIG. 4 is a cross-sectional view showing a solar cell manufactured in accordance with an exemplary embodiment of the present invention. FIGS. 5A, 5B, 5C and 5D are process diagrams schematically illustrating a method of manufacturing the solar cell of FIG. 4.

A solar cell according to the present embodiment is substantially the same as that according to the embodiment disclosed in connection with FIG. 1 except for at least a first low density pattern LDP1 and a second low density pattern LDP2 formed between the neighboring first doped pattern DP1 and the second doped pattern DP2.

Moreover, a method of manufacturing a solar cell according to the present embodiment is substantially the same as that according to the embodiment described in connection with FIGS. 3A-3I except for at least the steps described in connection with FIGS. 3B to 3E. The same reference numerals refer to the same or substantially the same elements as those described in connection with FIGS. 3A-3I.

Referring to FIGS. 3A, 4 and 5A, a diffusion protective pattern DB2 is formed over the first surface to include at least one opening that corresponds to the first area A1 or second area A2.

The processes prior to the formation of the diffusion protective pattern DB2 on the base substrate 210 are the same or substantially the same as those described in connection with FIG. 3A.

Referring to FIGS. 4, and 5A and 5B, a first mask SM1 having at least one opening that corresponds to the first area A1 is disposed over the base substrate 210 and the first dopant is doped into the first area A1 of the base substrate 210 to form the first doped pattern DP1 on the first area A1.

Referring to FIGS. 4, and 5B and 5C, a second mask SM2 having at least one opening that corresponds to the second area A2 is disposed over the base substrate 210 and the second dopant is doped on the second area A2 of the base substrate 210 to form the second doped pattern DP2 on the second area A2.

In this case, a thickness T2 of the diffusion protective pattern DB2 may be thinner than the first thickness T1 of the diffusion protective pattern DB1 of FIGS. 3B-3D. For example, the second thickness T2 of the diffusion protective pattern DB2 may be about 0.1 μm to about 10 μm.

Thus, the first dopant may be doped outside of the first area A1. However, a small amount of the first dopant is only doped outside of the first area A due to the diffusion protective pattern DB2. Part of the first dopant doped outside of the first area A1 forms the first low density pattern LDP1. The first low density pattern LDP1 may include a P− area.

Similarly, the second dopant may be doped off the second area A2, however, a small amount of the second dopant is only doped off the second area A2 due to the diffusion protective pattern DB2. Part of the second dopant doped off the second area A2 forms the second low density pattern LDP2. The second low density pattern LDP2 may include an N− area.

The first low density pattern LDP1 and the second low density pattern LDP2 may be formed between the first doped pattern DP1 and second doped pattern LP2 under the diffusion protective pattern DB2. The first low density pattern LDP1 extends from the first doped pattern DP1 while abutting or being adjacent to the first surface, and the second low density pattern DLP2 extends from the second doped pattern DP2 while abutting or being adjacent to the first surface.

Although the diffusion protective pattern DB2 has low concentration and the first low density pattern LDP1 contacts the second low density pattern LDP2, holes and electrons are only delivered to the first doped pattern DP1 and the second doped pattern DP2 but not to the first and second low density patterns LDP1 and LDP2 because a concentration of the first low density pattern LDP1 is lower than that of the first doped pattern DP1 and a concentration of the second low density pattern LDP2 is lower than that of the second doped pattern DP2.

As a result, the first doped pattern DP1 doped with the first dopant and the second doped pattern DP2 doped with the second dopant may be electrically insulated from each other, so that a short circuit may be prevented from occurring between the first doped pattern DP1 and the second doped pattern DP2.

Referring to FIGS. 4, 5C and 5D, the diffusion protective pattern DB2 is removed.

The subsequent processes are the same or substantially the same as those described in connection with FIGS. 3F to 3I.

According to the present embodiment, the diffusion protective pattern DB2 may prevent a short circuit between the first doped pattern DP1 and the second doped pattern DP2 similarly to the diffusion protective pattern DB1 described in the exemplary embodiment of FIGS. 1-3I. Moreover, the diffusion protective pattern DB2 may be formed to have a lower height than that of the diffusion protective pattern DB1, and thus, manufacturing costs may be further reduced.

As described above, since the first dopant and the second dopant may be respectively doped in the first area and the second area by using the first mask and the second mask, respectively, manufacturing costs and processing time may be decreased. Moreover, the first and second dopants may be accurately doped in the first and second areas, respectively, by the diffusion protective pattern, and this may prevent a short circuit that may occur due to a misalignment between the first doped pattern and the second doped pattern. As a consequence, a high-efficiency solar cell may be manufactured.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims.

What is claimed is:

1. A method of doping impurities, comprising:
forming a diffusion protective pattern on a substrate that contains a first area and a second area;
doping a first dopant in the first area by using a first mask to form a first doped pattern; and
doping a second dopant in the second area by using a second mask to form a second doped pattern wherein the diffusion protective pattern has at least one opening that corresponds to the first area or the second area.

2. The method of claim 1, wherein the diffusion protective pattern is formed between the first and second areas.

3. The method of claim 2, further comprising:
removing the diffusion protective pattern after the first and second doped patterns are formed.

4. The method of claim 2, wherein the substrate comprises a Group IV element, wherein one of the first and second dopants comprises a Group III element, and the other of the first and second dopants comprises a Group V element.

5. The method of claim 2, wherein forming the diffusion protective pattern is performed by one of a screen printing method, an ink printing method and a photolithograph method.

6. The method of claim 2, wherein the diffusion protective pattern comprises at least one of a silicon oxide (SiOx) material and a silicon nitride (SiNx) material.

7. A method of manufacturing a solar cell, comprising:
forming a diffusion protective pattern having a first thickness on a substrate having a first area and a second area;
doping a first dopant in the first area by using a first mask to form a first doped pattern and doping a second dopant in the second area by using a second mask to form a second doped pattern;
removing the diffusion protective pattern after the first and second doped patterns are formed; and
forming a first metal pattern electrically connected to the first doped pattern and a second metal pattern electrically connected to the second doped pattern on a first surface of the substrate, wherein the diffusion protective pattern has at least one opening that corresponds to the first area or the second area and wherein the first metal pattern and the second metal pattern are spaced apart from each other.

8. The method of claim 7, wherein the diffusion protective pattern is formed between the first and second areas.

9. The method of claim 8, wherein forming the diffusion protective pattern is performed by one of a screen printing method, an ink printing method, and a photolithograph method.

10. The method of claim 8, wherein an interval between two neighboring openings of the diffusion protective pattern is about 1 μm to about 300 μm.

11. The method of claim 8, wherein the substrate comprises a second dopant.

12. The method of claim 11, further comprising:
doping the second dopant in a second surface of the substrate.

13. The method of claim 8, further comprising:
forming a convex-concave pattern on the second surface of the substrate.

14. The method of claim 13, further comprising:
forming a first passivation layer on the second surface of the substrate on which the convex-concave pattern is formed.

15. The method of claim 14, further comprising:
forming a reflection protective layer on the second surface of the substrate on which the first passivation layer is formed.

16. The method of claim 8, further comprising:
forming a second passivation layer on the first surface on which the first doped pattern and the second doped pattern are formed.

17. The method of claim 16, further comprising:
removing the second passivation layer to form a first contact hole contacting the first doped pattern and the first metal pattern, and a second contact hole contacting the second doped pattern and the second metal pattern.

18. The method of claim 8, wherein forming the diffusion protective pattern includes forming the diffusion protective pattern to have a second thickness thinner than the first thickness, and wherein the method further comprises forming a first low density pattern which has a lower concentration than the first doped pattern and a second low density pattern which has a lower concentration than the second doped pattern under the diffusion protective pattern between the first doped pattern and the second doped pattern during forming of the first doped pattern and the second doped pattern.

19. A solar cell comprising:
a substrate comprising,
a first doped pattern formed on a first surface of the substrate and doped with a first dopant,
a second doped pattern formed on the first surface of the substrate and doped with a second dopant,
a first low density pattern formed between the first and second doped patterns and having a lower concentration than the first doped pattern, and
a second low density pattern formed between the first and second doped patterns and having a lower concentration than the second doped pattern;
a first metal pattern formed on the first surface of the substrate and electrically connected to the first doped pattern; and
a second metal pattern formed on the first surface of the substrate and electrically connected to the second doped pattern, wherein the second metal pattern is spaced apart from the first metal pattern.

20. The solar cell of claim 19, wherein the substrate further comprises a layer doped with the second dopant on a second surface of the substrate.

21. The solar cell of claim 19, wherein the second surface of the substrate has a convex-concave pattern.

22. The solar cell of claim 21, further comprising a reflection protective layer on the second surface of the substrate.
